(19) United States
(12) Patent Application Publication
(10) Pub. No.: US 2005/0114751 A1
(43) Pub. Date: May 26, 2005

(54) Two input differential cyclic accumulator

(76) Inventor: Steve James Ungstad, Colorado Springs, CO (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/718,550

(22) Filed: Nov. 24, 2003

(51) Int. Cl. H03M 13/00

(52) U.S. Cl. 714/781

(57) ABSTRACT

An apparatus and method to find CRC protected data packets by updating a cyclic redundancy checks (CRC) sum calculated from a data stream of CRC protected packets by adding new data while subtracting an effect of old data, and checking the updated CRC sum for a predetermined result. The apparatus includes a m-length memory to store a data stream an n-length accumulator to accumulate a CRC sum from the data. The apparatus includes a remainder circuit to feedback the data leaving the accumulator to the accumulator based on a predetermined CRC polynomial and a subtraction circuit to remove the effect of data leaving the memory from the accumulator. A CRC sum validation circuit checks the CRC sum for a valid result to indicate that the data packet protected by the CRC is located.

### BACKGROUND OF THE INVENTION

1. Field of Invention

The present invention is directed to error correction and signal detection and more particularly, the invention involves a method of searching data streams for data blocks protected by valid cyclic redundancy checks (CRC).

2. Description of the Related Art

To facilitate the detection and correction of errors in data streams, data is typically encoded using well-known codes such as CRC codes. For example, data streams that carry ATM cells depend on detecting valid header CRCs to delineate the ATM cells.

A conventional method and apparatus to scan for a data packet protected by n bit CRC is illustrated in FIG. 1, where typically n=8, 16, 32 etc. A receiver 10 receives a data input from an outside source. The outside source can be a data stream from a network connection, the data stream can be read from a disk drive, and the data stream could be any other serial data stream.

The received input data is typically stored, assuming that the block boundaries are delineated, by a machine, for example a computer system that will store the data in a buffer 24 or other suitable memory storage. A certain number of predetermined size blocks of the data stream are retained in buffer 24, before another process stores the received data to disks or other memory for other uses.

In general as data comes in to the apparatus as a bitwise stream, a CRC accumulator 12 sums the data. The accumulator 12 is reset in operation 14 each time a new data block is to be checked for a valid CRC. The blocks in FIG. 1 are illustrative and the circuitry implementing the blocks is well known and will not be described in detail. Byte wide implementations are similar in concept to the bitwise implementation and are handled in a well known manner and are not discussed.

The accumulated sum is checked in operation 16 at the end of the data block. The CRC accumulator 12 is cleared, or reset, at the beginning of each data block input, and then at the end of the data block of a predetermined size, the value of the CRC accumulator is checked to see that it comes out to a valid value that varies depending on the application.

As bits of the input data are shifted through the CRC accumulator 12, a new bit of data is input on the right end of the n-length CRC accumulator 12 and the n-th bit is shifted out of the left end of the accumulator 12. The n-th bit shifted out is then fed back into the accumulator 12. The n-th bit shifted out is represented in the CRC accumulator R(0) to R(n−1) by a combination of lesser bits. This is accomplished by using a standard n-length CRC polynomial constant 20 that is chosen based on the application and the bit length. The n-length CRC polynomial constant 20 is combined with the n-length CRC accumulator 12 by operation of a bitwise exclusive-or 22 that depends on the n-length CRC polynomial constant 20 chosen. Logic gates for active bits of the n-length CRC polynomial constant 20 chosen perform one's-compliment-addition to combine the n-length CRC polynomial constant 20 with the CRC accumulator 12. One's compliment addition is equivalent to a bitwise exclusive-or operation. Once a valid accumulated sum is detected in operation 16 the system will continue to scan for other data blocks with valid accumulated sums. For example, in asynchronous transfer mode (ATM) once a valid 5-byte header, called the header error control (HEC) is detected, a set number (approximately 7) of additional valid headers must be detected in the expected positions of the length of an ATM cell, i.e. 53 bytes, apart, before synchronization is declared. The system then continues to scan to detect the loss of synchronization, which also requires a set number of invalid HEC codes before synchronization is declared lost.

A standard ATM header is only 5 bytes long, however, current methods and apparatus have difficultly handling larger data blocks or cells as the circuitry involved becomes large and complex. What is needed is a method and apparatus that can efficiently detect larger CRC protected data packets in high-speed data streams.

### SUMMARY OF THE INVENTION

It is an aspect of the present invention to provide a method and apparatus that can efficiently locate data blocks of varying sizes that are protected by CRC.

According to an aspect of the present invention a method for updating a cyclic redundancy check (CRC) sum calculated from a data stream of CRC protected packets by adding new data while subtracting an effect of old data, and checking the updated CRC sum for a predetermined result is provided.

According to an aspect of the invention, a method of scanning a data stream for CRC protected packets is provided that includes receiving a data stream and accumulating the data stream to compute a CRC sum. The CRC sum in the accumulator is updated as more data is received by adding the new data while subtracting out the old data and checking the CRC sum for a predetermined result.

In an alternative aspect the method is adapted to a network for use during communication.

In an alternative aspect of the invention a system for scanning a data stream for data blocks protected by CRC is provided. The system receives a data stream, stores the data stream and accumulates a CRC sum of the data stream. The CRC sum is adjusted by adding new data and subtracting out old data using the exclusive-or function. Applying the exclusive-or function to the accumulator and a predetermined CRC polynomial constant of the same length as the accumulator adds new data. Applying the exclusive-or function to the accumulator and an extrapolated version of the predetermined CRC polynomial constant taken to the m-th term, where m is the size of the CRC protected data block, temporarily stored in the buffer, subtracts the affect of old data out of CRC accumulator. The adjusted CRC sum is compared to the value of a predetermined result that if matched would indicate that a valid CRC protected data block resides in buffer.

In another aspect of the invention, a receiver to scan for data packets protected by CRC is provided that includes a m-length memory to store a data stream an n-length accumulator to accumulate a CRC sum from the data. The receiver includes a remainder circuit to feedback the data leaving the accumulator to the accumulator based on a predetermined CRC polynomial constant and a subtraction circuit to remove the effect of data leaving the memory from the accumulator. A CRC sum validation circuit checks the CRC sum for a valid result to indicate that the data packet protected by the CRC is located.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 is a block diagram of a conventional method of calculating a CRC, to search a data stream for a valid CRC.

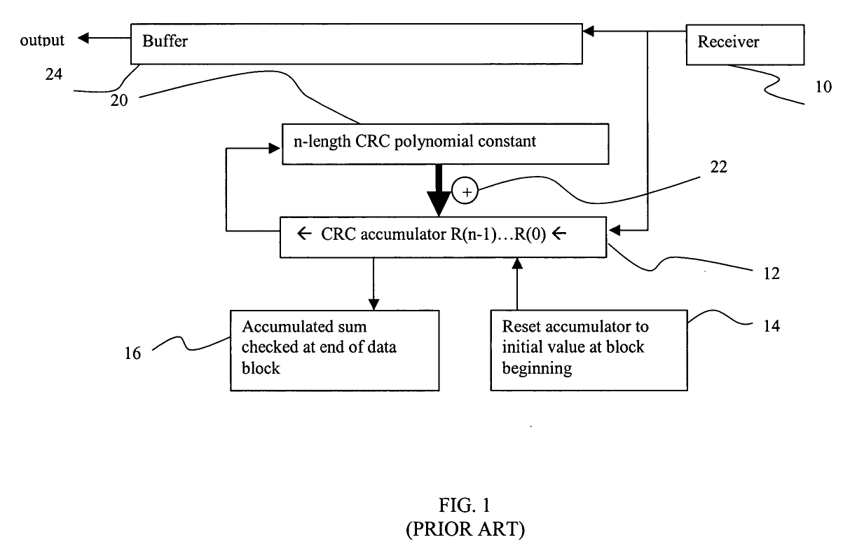

FIG. 2 is a flow chart illustrating the operation of a method of searching for a CRC protected data packet in accordance with an embodiment of the present invention.

FIG. 3 is a block diagram of an apparatus to find a data packet protected by a CRC in a data stream in accordance with an embodiment of the present invention.

FIG. 4 is a block diagram of an apparatus to find a data packet protected by a CRC in a data stream using a byte wide operation in accordance with an embodiment of the present invention.

### DETAILED DESCRIPTION OF THE INVENTION

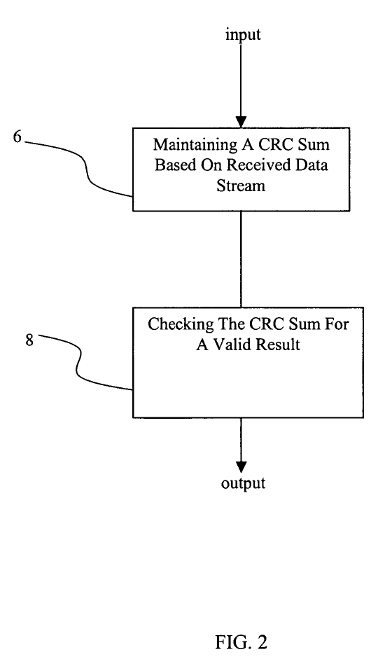

FIG. 2 is a flow chart illustrating the operation of a method of searching for a CRC protected data packet in a data stream. In operation 6, a cyclic redundancy check (CRC) sum is maintained by updating the CRC sum based on the received data stream. The CRC sum is calculated from a data stream having CRC protected data packets by adding new data while subtracting an effect of old data. In operation 8, the updated CRC sum is checked for a predetermined result. If the CRC sum matches the predetermined result a data packet protected by CRC has been found and may be output for further processing and handling. A CRC may be referred to as a remainder, modulus, syndrome or a sum depending on the context and the mathematical analogy favored. For the sake of the present invention, these terms are well known and are used interchangeably. Other terms that may share a common meaning are “power, bit, and term”, as do data “packet, block, and cell”.

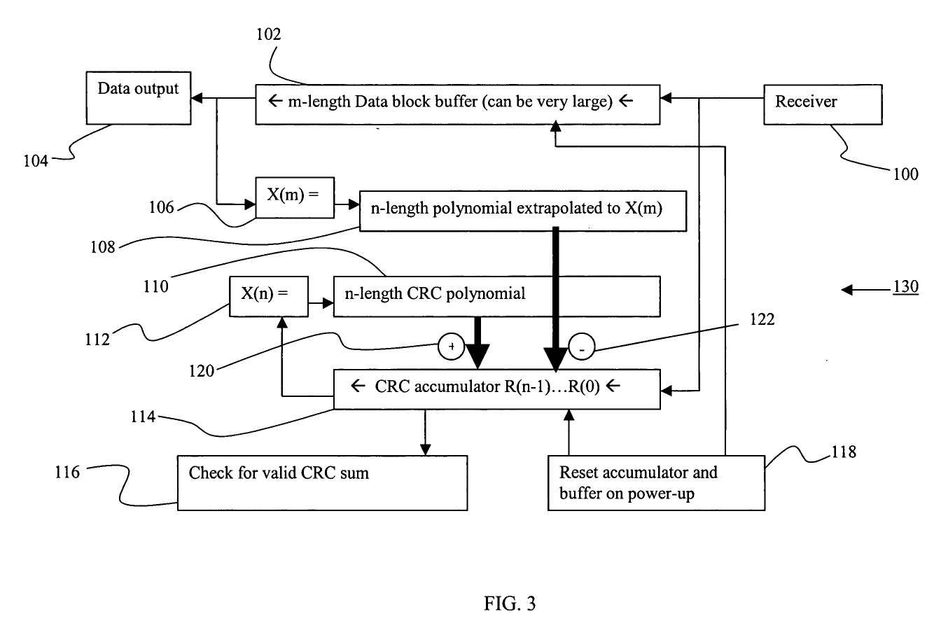

FIG. 3 is a block diagram illustrating a method and apparatus to find a data packet protected by a CRC in a data stream in accordance with an embodiment of the present invention. Referring to FIG. 3, when power is applied to the apparatus 130, a buffer 102 and a CRC accumulator 114 are reset to an initial value in operation 118 so that the buffer 102 and the CRC accumulator 114 are operating together. As receiver 100 receives a serial data stream, the m-length buffer 102 stores the data stream for later use. As the data is flowing into the buffer 102, the data is simultaneously being input bitwise into a CRC accumulator 114. The buffer 102 may be any data storage memory such as a shift register, stacks or RAM.

The CRC accumulator 114 is n-bits long based on the length of the CRC chosen. For example, 8, 16, or 32 bits in length if a CRC-8, CRC-16a, CRC-32 standard polynomial constant is chosen. As the n-th bit 112, represented by variable X(n), is shifted out of the CRC accumulator 114 a new data bit is shifted in to the CRC accumulator 114. The n-th bit 112 is converted into an n-length CRC polynomial 110 representing the n-th bit's remainder and is combined with the accumulator 114 by an exclusive-or operation 120 based on the active bits that correspond to the n-length CRC polynomial 110. The n-length CRC polynomial 110 is a standard CRC polynomial constant and may be chosen to be a desired length based on the application.

As the n-th bit 112 is shifted out the effect of the n-th bit 112 is added by exclusive-or gates 120 back in to the accumulator 114 and the effect of the most significant bit 106, illustrated in FIG. 3 as variable X(m), shifted out of the data buffer 102 is subtracted 122 out of the accumulator 114. The subtracting out operation is accomplished by extrapolating the same n-length CRC polynomial to the m-th power 108 and then performing the exclusive-or operation 122 with the CRC accumulator 114. By updating the remainder in the accumulator in this manner a representation of the data between two discrete points in the data stream is maintained. One's-compliment addition and one's-compliment subtraction are mathematically the same operation, being otherwise known as a bitwise exclusive-or operation. Thus, though depicted in FIG. 3 as a plus operation 120 and a minus operation 122, both operations are implemented as exclusive-or operations.

The CRC accumulator 114 is continuously checked for a valid accumulator sum constant in operation 116 to detect the boundary of the data block. For example, ATM often uses the remainder coset value 0×55 hex as the valid sum. The logic required to compare a data variable to a constant is well known and is not discussed herein.

Conceptually the present invention performs just three operations, adding what goes in and subtracting what went out to a current value that is being maintained and updated. This results in an efficient use of logic resources. For example, with ATM HEC, a conventional method scans data streams by adding 40 bits in parallel hardware to an 8-bit sum, requiring a 40×8 gate array for a hardware implementation. The present invention reduces this to a 3×8 gate array. The present invention if implemented in an ATM network may be located in the physical layer of the ATM, though it may also be implemented in the ATM layer.

For applications where the CRC protected packet is larger, the advantage becomes more dramatic. In this embodiment of the present invention, the accumulator logic requirement remains 3×n gates for any size data block, where n is the CRC length. As the size of the data block increases, only the packet buffer memory increases in size. Thus, stronger CRC or FEC codes may be used given the reduced costs associated with implementation using the present invention.

The present invention may be implemented in either hardware or software. Hardware implementation of CRC coding is well known in the art and will not be described in detail. For example, see U.S. Pat. No. 4,979,174 issued to Cheung et al. on Dec. 18, 1990. Software coding is also well known and specific discussion is omitted as the syntax of any appropriate software language could be derived from the method shown and described. A system that could implement the invention using software includes permanent or removable storage, such as magnetic and optical disks, RAM, ROM, FROM, EEPROM, etc. on which processes and data structures of the present invention can be stored and distributed. The processing may also be distributed via, for example, portions of a network such as a LAN, WAN, WLAN or the Internet.

Assume a data stream is being received in block 100, the data is stored in a buffer 102 and also is accumulated in the accumulator 114, when the buffer 102 holds a data block with a CRC the value of the CRC accumulator 114 will flash to a valid sum, for example 0×55 in ATM HEC. The remainder of the data flowing through the CRC accumulator 114 is combined with the accumulator via a feedback CRC polynomial. This operation is accomplished by the exclusive-or operation of the bit shifted out 112 of the accumulator via a predetermined n-length CRC polynomial 110 fed back into the CRC accumulator 114. The CRC accumulator 114 has another input from the end of the data buffer 102 that subtracts the influence of the old data that has already cycled through the CRC accumulator 114 several times, while a copy of that old data traverses the data block buffer 102. The effect of the old data is no longer the same as it was when it entered the CRC accumulator 114 and buffer 102 as it has circulated through the CRC accumulator 114 and the CRC feedback loop. For example, if a ‘1’ bit was added to the CRC accumulator 114 and the buffer 102 at the beginning of a scan, then after the n-length CRC polynomial 110 feedback has cycled the ‘1’ bit m times, making this the most significant bit in the buffer 102, the effect of the m-th bit on the CRC accumulator 114 is equal to the value of the n-length CRC polynomial extrapolated to the m-th term 108. So as a new bit comes into the buffer 102, the m-th prior bit is output from the left end of the buffer 102, and if that bit was ‘1”, the predetermined n-length CRC polynomial extrapolated to the m-th power 108 is subtracted 122 from the CRC accumulator 114. The effect of the m-th prior bit initially entering the accumulator 114 is negated as it passes out of buffer 102. Therefore, the CRC accumulator 114 can be maintained in a state that represents the remainder of only the data within the boundaries of the buffer 102. The data stream may thus be searched on a bit-by-bit basis to look for a valid CRC protected data block. The logic required is much simpler than that needed in previous methods as the present invention only needs inputs to read the accumulator value, the old data bit and the new data bit to update the accumulator to represent the next bit in the scan. When a valid CRC protected data block is found then the identified block could be stored or undergo error correction or other operations. The present invention would be compatible with other methods of forward error correction (FEC).

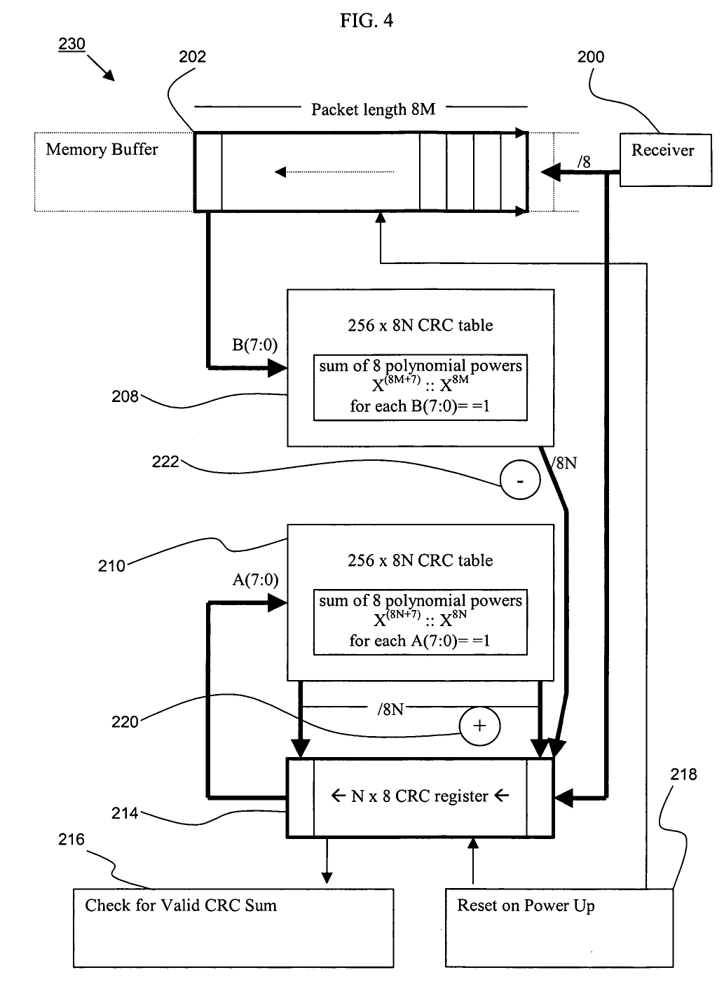

FIG. 4 is a block diagram of an apparatus to find a data packet protected by a CRC in a data stream using a byte wide operation in accordance with an embodiment of the present invention. Referring to FIG. 4, the CRC length and the data packet lengths are chosen to be multiples of 8 bits for efficiency of operation in byte wide systems. Often, byte wide error correction systems are implemented using software though it is not required. As in the system in FIG. 2, the CRC register 214, which performs the same function as the CRC accumulator 114 in FIG. 2, and the buffer 202 only need to be reset in operation 218 on power up or the first use of the system 230 and not for each data block that is going to be checked for a CRC. As a receiver 200 receives data from a data source, the data is stored in a memory buffer 202 and flows through the CRC register 214. As a byte is shifted out of the CRC register 214 the byte is added back to the accumulator by a feedback according to an N byte CRC polynomial that is pulled from a predetermined 256×8N CRC table by the exclusive-or operation 220. Concurrently, the effect of the most significant byte of the memory 202 corresponding to the m-th prior byte shifted into the CRC register 214 is subtracted out of the accumulator 214 by applying the exclusive-or operation 222 to each corresponding byte of the CRC register 214 based on the N byte CRC polynomial pulled from a predetermined 256×8N CRC lookup table that has been extrapolated to the M-th power. The CRC register 214 is continuously scanned for a valid CRC sum in operation 216. If the CRC sum maintained in the CRC register 214 matches the predetermined result in operation 216, a data packet protected by CRC has been found and may be output for further processing and handling.

An example of a VHSIC Hardware Description Language (VHDL) test set up of the present invention in ATM HEC used the standard I.432 CRC polynomial. Incoming data is added at the first bit, X(0), and is accumulated using the I.432 polynomial x⁸=x³+x+1. Data exiting the 40 bit header buffer is removed using the same polynomial extrapolated to x⁴⁰=x⁶+x⁵+x. The test code is the following:
Remainder(7)<=Remainder(6)
Remainder(6)<=Remainder(5) xor ShiftReg(39)
Remainder(5)<=Remainder(4) xor ShiftReg(39)
Remainder(4)<=Remainder(3)
Remainder(3)<=Remainder(2)
Remainder(2)<=Remainder(1) xor Remainder(7)
Remainder(1)<=Remainder(0) xor Remainder(7) xor ShiftReg(39)
Remainder(0)<=DataInput xor Remainder(7)
ShiftReg(39 downto 0)<=ShiftReg(38 downto 0) & DataInput
   This test VHDL code produces a remainder equal to the coset value (0×55) when the data in the 40-bit shift register represents a valid ATM header. In this example, Remainder( ) is a variable representing a bit in the accumulator 114, and ShiftReg( ) is a variable representing a bit in the 40-bit shift register or buffer 102. Xor is the exclusive-or logical operation, and <= is an assignment operator. The appearance of “xor Remainder(7)” 112 on the right side of the statements (x2,x1,x0) represents the feedback 110 to the accumulator 114 based on the CRC polynomial and “xor ShiftReg(39)” 106 represents the extrapolated CRC polynomial (x6,x5,x1) 108.

As described above, the present invention provides a method and apparatus for efficiently scanning a data stream for CRC protected data cells or blocks of any size. For example, scanning a 288-byte block of data only requires two calculations per scan step, whereas previous methods would require 288 calculations. A scan for a 2048-byte block would also only require two calculations per scan step versus 2048 calculations required by the previous method. Additionally, the present invention simplifies the required logic for initialization, as the present invention only needs to be initialized one time at power up rather than for each successive data scan. It is to be understood that the present invention can be utilized with network communications, such as WAN, LAN, or WLAN as well as scanning data located on hard disks or tapes that use CRC protected data blocks or cells.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

1. A method comprising:
updating a cyclic redundancy checks (CRC) sum calculated from a data stream of CRC protected packets by adding new data while subtracting an effect of old data; and
checking the updated CRC sum for a predetermined result.

2. The method of claim 1, further comprising:
initializing a m-length buffer and an n-length accumulator to calculate the CRC sum; and
storing the data stream in the m-length buffer.

3. The method of claim 2, wherein adding the new data comprises performing an exclusive-or operation between the accumulator and a predetermined feedback CRC polynomial.

4. The method of claim 2, wherein subtracting the effect of old data comprises performing an exclusive-or operation between the accumulator and a predetermined CRC polynomial extrapolated to the m-th power corresponding to the most significant bit of the m-length buffer.

5. The method of claim 2, wherein the m-length buffer and the n-length accumulator are initialized only once.

6. A network receiver adapted to carry out the method of claim 2.

7. A method comprising:
initializing a m-length buffer and an n-length accumulator;
storing a m-length data stream in the buffer;
accumulating a remainder of m-length data by bits in an n-length accumulator;
combining a predetermined n-length CRC polynomial extrapolated to the m-th power with the n-length accumulator;
combining a predetermined n-length CRC polynomial with the n-length accumulator; and
checking the accumulator for a predetermined result.

8. The method of claim 7, wherein the combining the n-length CRC polynomial includes performing the exclusive-or operation on the n-length accumulator and the n-length CRC polynomial corresponding to active bits in the predetermined n-length CRC polynomial; and
wherein the combining the n-length CRC polynomial extrapolated to the m-th power with the n-length accumulator includes performing the exclusive-or operation between the n-length accumulator and the n-length CRC polynomial extrapolated to the m-th bit.

9. A network receiver adapted to carry out the method of claim 8.

10. The method of claim 8, wherein the m-length buffer and the n-length accumulator are initialized only when the receiver is turned on.

11. A system comprising:
calculation means for updating a CRC sum computed from an accumulated data stream having data blocks protected by CRC by adding new data and subtracting out old data; and
validation means for comparing the updated CRC sum to a predetermined result to identify a complete data block protected by CRC.

12. The system of claim 11, wherein the calculation means further comprises:
feedback means for feeding data back into the accumulator according to a predetermined CRC polynomial of length n; and
subtraction means for subtracting the effect of old data from the means for accumulating.

13. The system of claim 12, wherein the subtraction means comprises extrapolating a predetermined CRC polynomial to a m-th term and performing an exclusive-or operation with the means for accumulating the data stream.

14. A receiver to scan for data packets protected by CRC comprising:
a m-length memory to store a data stream;
an n-length accumulator to accumulate a CRC sum from the data;
a remainder circuit to feedback the data leaving the accumulator to the accumulator based on a predetermined CRC polynomial;
a subtraction circuit to remove the effect of data leaving the memory from the accumulator; and
a CRC sum validation circuit to check the CRC sum for a valid result to indicate that the data packet protected by the CRC is located.

15. The receiver of claim 14, wherein the m-length memory and the n-length accumulator are initialized to a predetermined value when power is supplied to the receiver.

16. The receiver of claim 14, wherein the memory is a buffer.

17. The receiver of claim 14, wherein the memory is tangible media capable of being read by a machine.

18. The receiver of claim 14, wherein the subtraction circuit includes a predetermined CRC polynomial extrapolated to the m-th term and an exclusive-or is performed using the extrapolated CRC polynomial and the accumulator.

19. The receiver of claim 18, wherein the data is input into the memory and the accumulator by bits.

20. The receiver of claim 18, wherein the data is input into the memory and the accumulator by bytes.
